(19) United States
(12) Patent Application Publication
(10) Pub. No.: US 2024/0365613 A1
(43) Pub. Date: Oct. 31, 2024

(54) DISPLAY DEVICE AND MANUFACTURING METHOD THEREOF

(71) Applicant: Samsung Display Co., Ltd., Yongin-Si (KR)

(72) Inventors: Sun Kwun SON, Yongin-si (KR); Sang Yong NO, Yongin-si (KR); Dong Hee SHIN, Yongin-si (KR)

(21) Appl. No.: 18/624,434

(22) Filed: Apr. 2, 2024

(30) Foreign Application Priority Data
Apr. 28, 2023 (KR) 10-2023-0056275

(51) Int. Cl. H10K 59/131; H10K 59/121

(52) U.S. Cl. CPC H10K 59/131; H10K 59/1216

(57) ABSTRACT

A display device is disclosed that includes a substrate, first through fourth conductive layers, first through fourth insulating layers, a semiconductor layer, and a light emitting layer. The first conductive layer is disposed on the substrate and includes a first conductive pattern. The first insulating layer is disposed on the first conductive layer. The semiconductor layer is disposed on the first insulating layer and includes a first channel region and a capacitor pattern. The second insulating layer is disposed on the semiconductor layer. The second conductive layer is disposed on the second insulating layer and includes a first gate electrode overlapping the first channel region. The third insulating layer is disposed on the second conductive layer. The third conductive layer is disposed on the third insulating layer and includes a common electrode. The fourth insulating layer is disposed on the third conductive layer. The fourth conductive layer is disposed on the fourth insulating layer and includes a plurality of pixel electrodes. The light emitting layer is disposed between the pixel electrode and the common electrode. The first gate electrode is electrically connected to the first conductive pattern through a first opening formed in the first insulating layer and the second insulating layer. The pixel electrode is electrically connected to the capacitor pattern. The capacitor pattern overlaps the first conductive pattern with the first insulating layer interposed therebetween to form a capacitor.

### CROSS-REFERENCE TO RELATED APPLICATION

This application claims priority to and the benefit of Korean Patent Application No. 10-2023-0056275 filed at the Korean Intellectual Property Office on Apr. 28, 2023, the entire contents of which are incorporated herein by reference.

### BACKGROUND

### (a) Technical Field

The present disclosure relates to a display device and a manufacturing method thereof.

### (b) Description of the Related Art

A display device includes a plurality of pixels that are units for displaying an image.

There are various types of display devices including light-emitting diode display devices. Each pixel of a light-emitting display device includes a light emitting diode that contains a cathode, an anode, and a luminescent part, and a pixel circuit that includes multiple transistors and at least one capacitor to operate the light emitting diode.

The pixel circuit is connected to various signal lines and voltage lines, such data lines and driving voltage lines.

The plurality of transistors may include at least one switching transistor and a driving transistor.

The switching transistor receives a data signal according to the scan signal and transfers the corresponding voltage to the driving transistor, and the driving transistor is directly or indirectly connected to the light emitting diode to control the amount of driving current delivered to the light emitting diode so that each pixel can achieve a desired luminance.

A manufacturing process of the display device includes a photolithography process of exposing light using at least one mask.

### SUMMARY

During the manufacturing process of the display device, as the number of exposure masks increases, the cost of the display device may increase.

Embodiments of the present disclosure may provide a display device with a reduced manufacturing cost.

In the manufacturing process of a display device, when a pixel circuit is implemented with as few layers as possible using a minimum number of masks, display defects such as horizontal crosstalk or intercolor crosstalk may occur due to coupling between layers.

The present disclosure is intended to prevent the occurrence of display defects such as horizontal crosstalk or intercolor crosstalk by reducing coupling between layers even when a pixel circuit is implemented with a small number of layers.

A display device according to an embodiment includes a substrate, a first conductive layer disposed on the substrate and including a first electrode pattern, a first insulating layer disposed on the first conductive layer, a semiconductor layer disposed on the first insulating layer and including a first channel region and a capacitor pattern, a second insulating layer disposed on the semiconductor layer, a second conductive layer disposed on the second insulating layer and including a first gate electrode overlapping with the first channel region, a third insulating layer disposed on the second conductive layer, a third conductive layer disposed on the third insulating layer and including a common electrode, a fourth insulating layer disposed on the third conductive layer, a fourth conductive layer disposed on the fourth insulating layer and including multiple pixel electrodes, and a light emitting layer located between the pixel electrodes and the common electrode. The first gate electrode is electrically connected to the first electrode pattern through a first opening formed in the first and second insulating layers the pixel electrode is electrically connected to the capacitor pattern, and the capacitor pattern forms a capacitor overlapping with the first electrode pattern with the first insulating layer in between.

The fourth insulating layer may have a plurality of second openings positioned on the common electrode, and the light emitting layer may include a portion positioned in the second openings.

The display device may further include a separation member disposed on a portion of the fourth insulating layer, and the plurality of pixel electrodes may be spaced apart from each other with the separation member interposed therebetween.

The above-mentioned separation member may include a portion forming a plurality of closed curves surrounding each of the plurality of pixel electrodes in a planar view.

The fourth conductive layer may further include a separation pattern electrically and physically separated from the plurality of pixel electrodes and positioned on the separation member.

The second conductive layer includes a first connecting member that is electrically connected to the capacitor pattern through the second opening formed in the second insulating layer, the first pixel electrode among the plurality of pixel electrodes can be electrically connected to the first connecting member through the third opening formed in the fourth insulating layer and the third insulating layer.

A second pixel electrode among the plurality of pixel electrodes may be electrically connected to the capacitor pattern through a fourth opening formed in the fourth insulating layer, the third insulating layer, and the second insulating layer.

The second conductive layer further includes a first connecting member electrically connected to the capacitor pattern through a second opening formed in the second insulating layer, and the third conductive layer comprises a first connecting member formed in the third insulating layer and a first bridge electrically connected to the first connecting member through three openings, wherein a first pixel electrode among the plurality of pixel electrodes is electrically connected to the first bridge through a fourth opening formed in the fourth insulating layer.

The third conductive layer further includes a second bridge electrically connected to the capacitor pattern through a fifth opening formed in the third insulating layer and the second insulating layer, and a second pixel electrode among the plurality of pixel electrodes. It may be electrically connected to the second bridge through a sixth opening formed in the fourth insulating layer.

The first conductive layer may further include a common voltage line, the second conductive layer may further include a connecting member electrically connected to the common voltage line, and the common electrode may be electrically connected to the connecting member.

The common electrode may have an opening having a location and shape corresponding to that of the first gate electrode.

The first conductive layer may include common voltage lines, driving voltage lines, initialization voltage lines, and multiple data lines, and the semiconductor layer may include multiple first semiconductor patterns electrically connected to the multiple data lines, and a second semiconductor pattern containing the first channel area, the second semiconductor pattern can be electrically connected to the driving voltage line, and the common electrode can be electrically connected to the common voltage line.

The first conductive layer further includes a second conductive pattern spaced apart from the first conductive pattern, the second conductive pattern overlaps the first channel region, and the second conductive pattern is electrically connected to the capacitor pattern.

A display device according to one embodiment includes a substrate, a first conductive layer disposed on the substrate and including a first electrode pattern, a semiconductor layer disposed on the first conductive layer and including a first channel region and a capacitor pattern, a second conductive layer disposed on the semiconductor layer and including a first gate electrode overlapping with the first channel region, a third conductive layer disposed on the second conductive layer and including a first electrode, a fourth conductive layer disposed on the third conductive layer and including multiple second electrodes, and a light emitting layer disposed between the first electrode and the second electrodes. The first gate electrode is electrically connected to the first electrode pattern, the second electrode is electrically connected to the capacitor pattern, the capacitor pattern overlaps with the first electrode pattern to form a capacitor, and the first channel region and the capacitor pattern are integrally formed.

A separation member disposed on the third conductive layer may be further included, and the plurality of second electrodes may be spaced apart from each other with the separation member interposed therebetween.

The separation member may include a portion forming a plurality of closed curved lines surrounding each of the plurality of second electrodes in a plan view.

The fourth conductive layer may further include a separation pattern electrically and physically separated from the plurality of pixel electrodes and positioned on the separation member.

The second electrode may be electrically connected to the capacitor pattern through at least one first connecting member included in at least one of the second conductive layer and the third conductive layer.

The first conductive layer may further include a common voltage line, and the first electrode may be electrically connected to the common voltage line through at least one second connecting member included in the second conductive layer.

The first electrode may have an opening corresponding to the first gate electrode.

According to the embodiments, the manufacturing cost of the display device may be reduced.

In addition, even if a pixel circuit is implemented with a small number of layers, coupling between layers can be reduced to prevent display defects such as horizontal crosstalk or inter-color crosstalk from occurring.

### BRIEF DESCRIPTION OF THE DRAWINGS

FIG. 1 is an equivalent circuit diagram of one pixel of a display device according to an embodiment.

FIG. 2 is a top plan view of some layers of a plurality of pixels of a display device according to an embodiment.

FIG. 3 is a top plan view of some layers of a plurality of pixels of a display device according to an embodiment.

FIG. 4 is a cross-sectional view of a display device shown in FIG. 2 and FIG. 3 cut along line A1-A2.

FIG. 5 is a cross-sectional view of a display device shown in FIG. 2 and FIG. 3 cut along line A3-A4.

FIG. 6 is a cross-sectional view of a display device shown in FIG. 2 and FIG. 3 cut along line A5-A6.

FIG. 7 is a cross-sectional view of a display device shown in FIG. 2 and FIG. 3 cut along line A7-A8.

FIG. 8 is a cross-sectional view of a display device shown in FIG. 2 and FIG. 3 cut along line A1-A2.

FIG. 9 is a cross-sectional view of a display device shown in FIG. 2 and FIG. 3 cut along line A3-A4.

FIG. 10 is a cross-sectional view of a display device shown in FIG. 2 and FIG. 3 taken along line A5-A6.

FIG. 11 is a cross-sectional view of a display device shown in FIG. 2 and FIG. 3 cut along line A7-A8.

FIG. 12 is a cross-sectional view of a display device shown in FIG. 2 and FIG. 3 cut along line A3-A4.

FIG. 13 is a schematic cross-sectional view of a display device according to an embodiment.

### DETAILED DESCRIPTION OF THE EMBODIMENTS

Hereinafter, various embodiments of the present invention will be described in detail with reference to the accompanying drawings so that those skilled in the art can easily carry out the present invention.

In order to clearly describe the present inventive concept, parts irrelevant to the description are omitted, and the same reference numerals are assigned to the same or similar constituent elements throughout the specification.

In addition, since the size and thickness of each component shown in the drawings are arbitrarily shown for convenience of explanation and do not represent actual size or thickness.

In the drawings, the thickness is shown enlarged to clearly express the various layers and regions.

And in the drawings, for convenience of explanation, the thicknesses of some layers and regions are exaggerated.

In addition, when a part such as a layer, film, region, plate, etc. is said to be “above” or “on” another part, this includes not only the case where it is “directly on” the other part, but also the case where another part exists in the middle thereof.

Conversely, when a part is said to be “directly on” another part, it means that there is no other part in between.

In addition, being “above” or “on” a reference part means being positioned above or below the reference part, and does not necessarily mean being positioned above or on it in the opposite direction of gravity.

In addition, throughout the specification, when a certain component is said to “include,” it means that it may further include other components without excluding other components unless otherwise stated.

Also, throughout the specification, when a “planar image” is referred to, it means when the target part is viewed from above, and when it is referred to as “cross-sectional image,” it means when the cross-section of the target part cut vertically is viewed from the side.

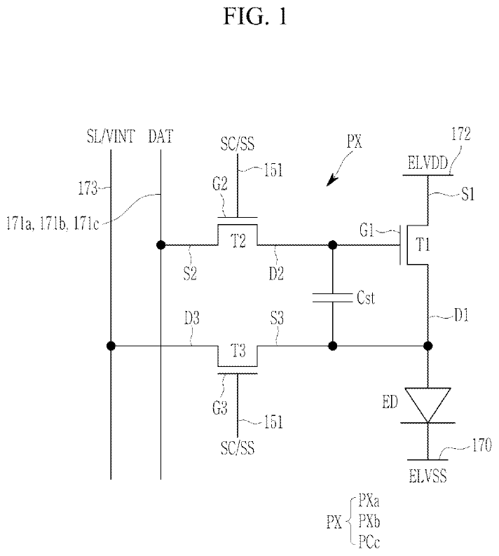

A display device according to an embodiment will be described with reference to FIG. 1.

FIG. 1 is an equivalent circuit diagram of one pixel of a display device according to an embodiment.

A display device according to an embodiment includes a plurality of pixels, which are units capable of displaying an image, and each pixel may include a light emitting device capable of emitting light in response to an image signal and a pixel circuit for driving the light emitting element.

A light emitting device included in each pixel may have a light emitting region that emits light.

The plurality of pixels may include pixels PXa, PXb, PXc adjacent to each other.

A pixel circuit of each of the pixels PXa, PXb, PXc may include at least one transistor and a pixel electrode connected thereto.

Light emitting regions of the plurality of pixels PXa, PXb, PXc may emit light of different colors to the outside.

For example, the plurality of pixels PXa, PXb, PXc may include a red pixel capable of emitting red light, a green pixel capable of emitting green light, and a blue pixel capable of emitting blue light.

However, the color of light emitted by the pixels PXa, PXb, PXc is not limited thereto and may vary.

In a plan view, light emitting regions of the plurality of pixels PXa, PXb, PXc may be arranged in various structures such as a rectangular matrix shape or a pentile matrix shape.

As shown in FIG. 1, each of the pixels PXa, PXb, PXc includes a pixel circuit including a plurality of transistors T1, T2, T3 and a capacitor Cst, and at least one light emitting device connected to the pixel circuit, it may include a light emitting diode ED.

In the present embodiment, an example in which one pixel PXa, PXb, PXc includes one light emitting diode ED will be mainly described.

The plurality of transistors T1, T2, T3 may include a first transistor T1 that is a driving transistor and a second transistor T2 and a third transistor T3 that are switching transistors.

Each transistor T1, T2, T3 includes a gate electrode G1, G2, G3, a first electrode S1, S2, S3, and a second electrode D1, D2, D3, and includes a semiconductor layer containing a channel, so that current flows or is blocked in the channel of the semiconductor layer depending on the voltage of the gate electrode G1, G2, G3.

Here, the first electrode S1, S2, S3 and the second electrode D1, D2, D3 can be a source electrode and a drain electrode respectively depending on the voltage applied to each transistor T1, T2, T3.

The gate electrode G1 of the first transistor T1 is connected to one terminal of the capacitor Cst, and the first electrode S1 of the first transistor T1 is a driving voltage line 172 transmitting the driving voltage ELVDD.

The second electrode D1 of the first transistor T1 is connected to the anode of the light emitting diode ED and the other terminal of the capacitor Cst.

The first transistor T1 receives a data voltage DAT according to the switching operation of the second transistor T2, and can supply driving current to the light emitting diode ED according to the voltage of the gate electrode G1.

In this case, the capacitor Cst may store and maintain the voltage of the gate electrode G1 of the first transistor T1.

The gate electrode G2 of the second transistor T2 is connected to the scan line 151 that transmits the scan signal SC/SS, the first electrode S2 of the second transistor T2 is connected to the data line 171a, 171b, 171c that transmits the data voltage DAT, and the second electrode D2 of the second transistor T2 can be connected to one end of the capacitor Cst and the gate electrode G1 of the first transistor T1.

For example, among the plurality of pixels PXa, PXb, PXc, the second transistor T2 of the first pixel PXa is connected to the data line 171a, and the second transistor T2 of the second pixel PXb is connected to the data line 171b, and the second transistor T2 of the third pixel PXc is connected to the data line 171c.

The second transistor T2 is turned on according to the scan signal SC to transfer the data voltage DAT to the gate electrode G1 of the first transistor T1 and one terminal of the capacitor Cst.

The gate electrode G3 of the third transistor T3 is connected to the scan line 151 that transmits the scan signal SC/SS, the first electrode S3 of the third transistor T3 is connected to the other end of the capacitor Cst, the second electrode D1 of the first transistor T1, and the anode of the light-emitting diode ED, and the second electrode D3 of the third transistor T3 is connected to the initialization voltage line 173 that delivers the initialization voltage VINT.

The third transistor T3 is turned on according to the scan signal SC/SS and transfers the initialization voltage VINT to the anode of the light emitting diode ED and the other terminal of the capacitor Cst so that the voltage at the anode of the light emitting diode ED can be initialized.

The initialization voltage line 173 may function as a sensing line SL that senses the voltage of the anode of the light emitting diode ED before applying the initialization voltage VINT.

Through the sensing operation, it may be confirmed whether the voltage of the anode is maintained at the target voltage.

The sensing operation and the initialization operation of transmitting the initialization voltage VINT may be separated in time, and the initialization operation may be performed after the sensing operation is performed.

Unlike shown in FIG. 1, the gate electrode G2 of the second transistor T2 and the gate electrode G3 of the third transistor T3 may be connected to different scan lines.

In this case, the gate electrode G2 of the second transistor T2 may receive the first scan signal SC, and the gate electrode G3 of the third transistor T3 may receive the second scan signal SS.

One terminal of the capacitor Cst is connected to the gate electrode G1 of the first transistor T1, and the other terminal is connected to the first electrode S3 of the third transistor T3 and the anode of the light emitting diode ED.

A cathode of the light emitting diode ED is connected to a common voltage line 170 that transmits the driving low voltage ELVSS.

The light emitting diode ED can emit light of luminance according to the driving current generated by the first transistor T1.

The structure of the pixel PX included in the display device according to the embodiment is not limited to the circuit shown in FIG. 1 and may have various pixel structures according to the type of display device.

Next, an example of an operation of each of the pixels PXa, PXb, PXc will be described with reference to FIG. 1.

When the third transistor T3 is turned on according to the second scan signal SS, an initialization operation or a sensing operation or both may be performed.

Here, an embodiment in which both the initialization operation and the sensing operation are performed will be mainly reviewed.

The sensing operation may be performed first before the initialization operation is performed.

That is, when the third transistor T3 is turned on, the initialization voltage line 173 serves as a sensing line SL to sense the voltage of the anode of the light emitting diode ED.

Through the sensing operation, it may be confirmed whether the voltage of the anode is maintained at the target voltage.

The initialization operation may be performed after the sensing operation.

In the initialization operation, the voltages of the other end of the capacitor Cst, the second electrode D1 of the first transistor T1, and the anode of the light emitting diode ED are changed to the initialization voltage VINT transmitted from the initialization voltage line 173.

The sensing operation and the initialization operation that transmits the initialization voltage VINT are separated in time, so that the area occupied by the pixels PXa, PXb, and PXc is reduced while using the minimum number of transistors, and the pixels PXa, PXb, and PXc are used in various ways.

As a result, resolution of the display device may be improved.

The second transistor T2 may be turned on according to the first scan signal SC along with the initialization operation or at a separate timing, and a write operation may be performed.

In the embodiment shown in FIG. 1, the second transistor T2 may be turned on simultaneously with the initialization operation.

That is, the second transistor T2 and the third transistor T3 may be connected to the same scan line 151 and turned on according to the same scan signal SC/SS.

The data voltage DAT may be input to the gate electrode G1 of the first transistor T1 and one terminal of the capacitor Cst through the turned-on second transistor T2 and stored therein.

The data voltage DAT and the initialization voltage VINT are applied to both ends of the capacitor Cst, respectively, by the initialization operation and the write operation.

In a state in which the third transistor T3 is turned on, even if an output current is generated in the first transistor T1, it can be output to the outside through the third transistor T3 and the initialization voltage line 173 to be converted to the light emitting diode ED may not be entered.

Also, depending on the embodiment, the driving voltage ELVDD may be applied as a low-level voltage, or the driving low-level voltage ELVSS may be applied as a high-level voltage during the write operation so that current does not flow through the light emitting diode ED.

Then, when the second transistor T2 is turned off according to the first scan signal SC, the high-level driving voltage ELVDD is applied to the first transistor T1 and the first transistor is stored in the capacitor Cst, the first transistor T1 generates and outputs an output current by the gate voltage of T1.

The output current of the first transistor T1 is input to the light emitting diode ED, and the light emitting period in which the light emitting diode ED emits light proceeds.

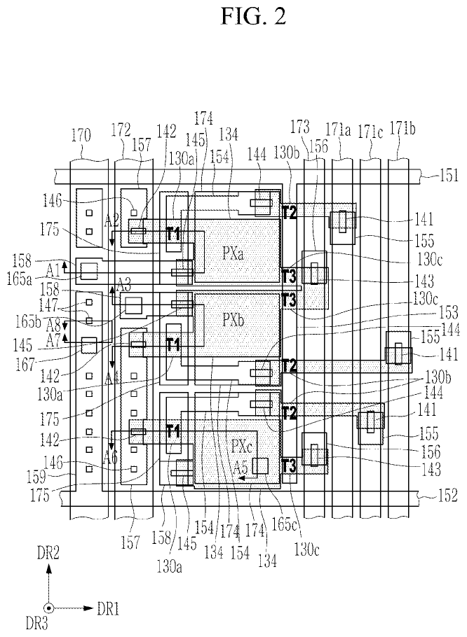

A detailed structure of a display device according to an embodiment will be described with reference to FIG. 2 to FIG. 7 along with FIG. 1.

FIG. 2 is a plan view of some layers of a plurality of pixels of a display device according to an embodiment,

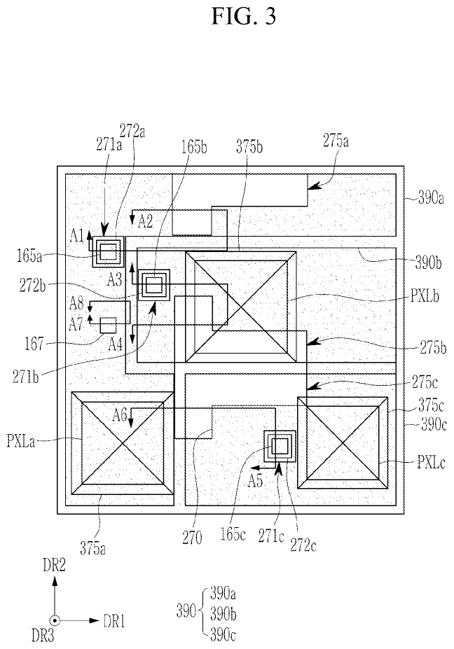

FIG. 3 is a plan view of some layers of a plurality of pixels of the display device according to an embodiment,

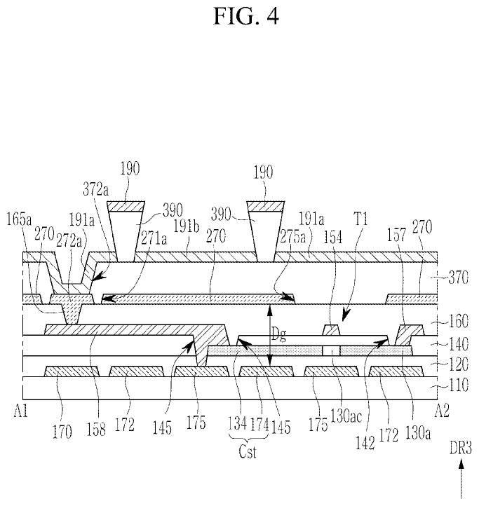

FIG. 4 is a plan view of FIG. 3, a cross-sectional view of the display device shown in FIG. 3 taken along line A1-A2,

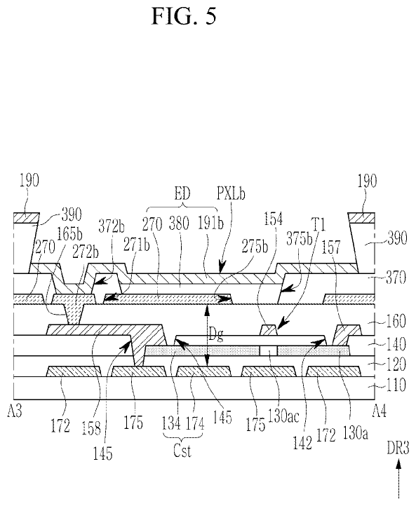

FIG. 5 is a cross-sectional view of the display device shown in FIG. 2 and FIG. 3 taken along line A3-A4,

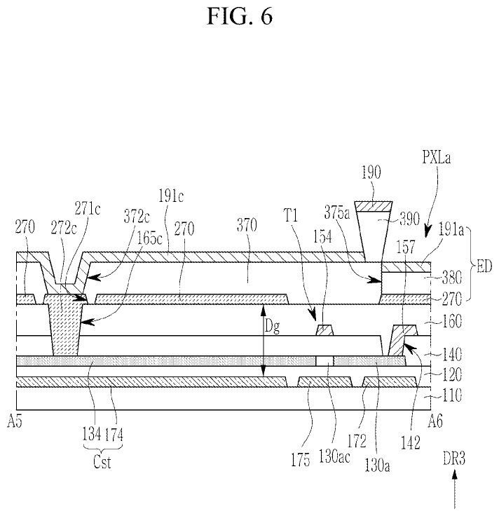

FIG. 6 is a cross-sectional view of the display device shown in FIG. 2 and FIG. 3 taken along line A5-A6, and

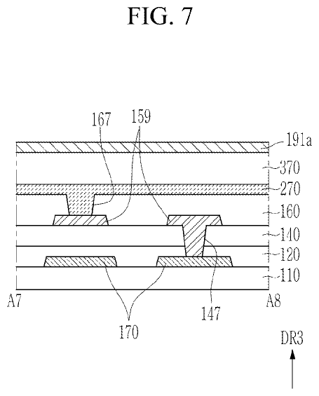

FIG. 7 is a cross-sectional view of the display device shown in FIG. 2 and FIG. 3 taken along line A7-A8.

FIG. 2 shows the structure of a pixel circuit including multiple transistors T1, T2, T3 and capacitors Cst of pixels PXa, PXb, PXc in a plan view parallel to the first direction DR1 and the second direction DR2, and FIG. 3 shows the structure of a light-emitting diode ED cathode and the structure above it.

Referring to FIG. 2, a plurality of pixel circuits of the plurality of pixels PXa, PXb, PXc are arranged in the second direction DR2.

A first pixel circuit belonging to the first pixel PXa is positioned at the top, a second pixel circuit belonging to the second pixel PXb is positioned below it, and a third pixel circuit belonging to the third pixel PXc is positioned at the bottom.

In this description, three adjacent pixels PXa, PXb, PXc are referred to as one pixel group.

Referring to FIG. 4 to FIG. 7, together with FIG. 2 and FIG. 3, which illustrate a stacked structure in a third direction DR3 vertical to a plan view, a display device according to an embodiment may include a substrate 110.

The substrate 110 may include an insulating material such as glass or plastic and may have flexibility.

On the substrate 110, a first conductive layer that includes a common voltage line 170, multiple data lines 171a, 171b, 171c, a driving voltage line 172, an initialization voltage line 173, multiple first conductive patterns 174, and multiple second conductive patterns 175 can be located.

Each of the island-shaped first conductive patterns 174 and each of the second conductive patterns 175 may be positioned in each of the pixels PXa, PXb, PXc.

In each of the pixels PXa, PXb, PXc, the first conductive pattern 174 and the second conductive pattern 175 may be adjacent to each other in the first direction DR1.

A planar area of the first conductive pattern 174 may be larger than the planar area of the second conductive pattern 175.

The common voltage line 170, the plurality of data lines 171a, 171b, 171c, the driving voltage line 172, and the initialization voltage line 173 each extend in the second direction DR2 to form a plurality of pixels PXa, PXb, PXc.

According to an embodiment, the common voltage line 170 and the driving voltage line 172 are adjacent to each other in the first direction DR1, and the plurality of data lines 171a, 171b, 171c and the initialization voltage line 173 are adjacent to each other in the first direction DR1, and the first conductive pattern 174 and the second conductive pattern 175 may be positioned between the driving voltage line 172 and the initialization voltage line 173.

However, the embodiment is not limited thereto.

A first insulating layer 120 may be positioned on the first conductive layer.

A semiconductor layer including a plurality of semiconductor patterns 130a, 130b, 130c and a capacitor pattern 134 may be positioned on the first insulating layer 120.

The semiconductor patterns 130a, 130b, 130c positioned in each of the pixels PXa, PXb, PXc are positioned on both sides of a channel region forming a channel of each of the plurality of transistors T1, T2, T3 described above, and it may include connected conductive regions.

FIGS. 4 to 6 show the channel region 130ac of the first transistor T1.

Capacitor pattern 134 positioned in each of the pixels PXa, PXb, PXc overlaps the first conductive pattern 174 on a plane and is connected to the semiconductor patterns 130a and 130c to form an integral body.

The capacitor pattern 134 may be connected to one end of the conductive region electrically connected to a pixel electrode, which will be described later. The capacitor pattern 134 may be connected to one end of the conductive region of the transistor T3.

The capacitor pattern 134 may be a conductive region having conductivity.

The capacitor pattern 134 positioned in each of the pixels PXa, PXb, PXc may be positioned between the semiconductor pattern 130a and the semiconductor pattern 130c and connected to each of the semiconductor patterns 130a and 130c.

In each of the pixels PXa, PXb, PXc, the semiconductor pattern 130b may be spaced apart from the semiconductor patterns 130a, 130c and the capacitor pattern 134, constituting an integral semiconductor pattern.

Referring to FIG. 2, according to an embodiment, the semiconductor pattern 130c of the first pixel PXa and the semiconductor pattern 130c of the second pixel PXb may be physically and electrically connected to each other.

According to this, the semiconductor patterns 130a, 130c and the capacitor pattern 134 of the first pixel PXa and the semiconductor patterns 130a, 130c and the capacitor pattern 134 of the second pixel PXb are connected to each other to form one integral body, so the pattern of the semiconductor layer can be achieved.

In each of the pixels PXa, PXb, PXc, the capacitor pattern 134 may overlap the first conductive pattern 174 with the first insulating layer 120 interposed therebetween to form the capacitor Cst.

The semiconductor layer including the capacitor pattern 134 may include a semiconductor material such as amorphous silicon, polycrystalline silicon, or an oxide semiconductor such as indium gallium zinc oxide (IGZO).

A second insulating layer 140 may be positioned on the semiconductor layer.

The second insulating layer 140 or the first insulating layer 120 and the second insulating layer 140 may have a plurality of openings 141, 142, 143, 144, 145, 146, 147.

The opening 141 may be positioned on each of the data lines 171a, 171b, 171c and the semiconductor pattern 130b overlapping them.

The opening 142 may be positioned on the driving voltage line 172 and the semiconductor pattern 130a overlapping the driving voltage line 172.

The opening 143 may be positioned on the initialization voltage line 173 and the semiconductor pattern 130c overlapping the initialization voltage line 173.

The opening 144 may be positioned on the first conductive pattern 174 and the semiconductor pattern 130b overlapping the first conductive pattern 174.

The opening 145 may be positioned on the second conductive pattern 175 and the capacitor pattern 134 overlapping the second conductive pattern 175.

The opening 146 may be positioned above the driving voltage line 172.

The opening 147 may be positioned above common voltage line 170.

On the second insulating layer 140, a scan line 151, a horizontal voltage line 152, a first gate electrode 154, a second gate electrode 153, and a plurality of connecting members 155, 156, 157, 158, 159 may be positioned.

The scan line 151 may extend substantially in the first direction DR1 and cross the common voltage line 170, the driving voltage line 172, the initialization voltage line 173, and the data lines 171a, 171b, 171c.

The horizontal voltage line 152 may extend substantially in the first direction DR1 and cross the common voltage line 170, the driving voltage line 172, the initialization voltage line 173, and the data lines 171a, 171b, 171c.

In a plan view, the scan line 151 and the horizontal voltage line 152 are spaced apart in the second direction DR2.

A pixel circuit of one pixel group may be positioned between the scan line 151 and the horizontal voltage line 152 in a plan view.

The first gate electrode 154 may include a portion overlapping the first conductive pattern 174 and a portion overlapping the semiconductor pattern 130a on a plane.

Referring to FIG. 2, the first gate electrode 154 can have a roughly bent rod shape, and the bending angle can be approximately a right angle.

The first gate electrode 154 may be electrically connected to one end of the conductive region of the semiconductor pattern 130b and the first conductive pattern 174 therebelow through the opening 144.

The first gate electrode 154 crosses the semiconductor pattern 130a and overlaps the channel region 130ac of the semiconductor pattern 130a.

The first gate electrode 154 corresponds to the gate electrode G1 of the first transistor T1 described above, and forms the first transistor T1 together with the semiconductor pattern 130a.

The first conductive pattern 174 which is electrically connected to the first gate electrode 154 may maintain the same voltage as the first gate electrode 154.

The channel region 130ac of the first transistor T1 may overlap the second conductive pattern 175.

The second conductive pattern 175 overlaps between the channel region 130ac of the first transistor T1 and the substrate 110 to prevent external light from reaching the channel region 130ac, thereby reducing leakage current, and characteristic deterioration can be reduced.

The second gate electrode 153 is electrically connected to the scan line 151 and may extend substantially in the second direction DR2 from the scan line 151. The second gate electrode 153 intersects the semiconductor patterns 130b, 130c of the pixels PXa, PXb, PXc and overlaps the channel regions of the semiconductor patterns 130b, 130c.

The second gate electrode 153 corresponds to the gate electrode G2 of the second transistor T2 and the gate electrode G3 of the third transistor T3 of FIG. 1. The second gate electrode 153 and the semiconductor patterns 130b, 130c for two transistors T2 and a third transistor T3 are formed.

The connecting member 155 may be electrically connected to the cutting areas of the semiconductor pattern 130b positioned at each pixel PXa, PXb, PXc through the opening 141 and the corresponding data lines 171a, 171b, 171c.

Accordingly, the semiconductor pattern 130b of the second transistor T2 may be electrically connected to the corresponding data lines 171a, 171b, 171c to receive the data voltage.

The connecting member 156 may be electrically connected to the initialization voltage line 173 and the conductive region of the other end of the semiconductor pattern 130c positioned in each of the pixels PXa, PXb, PXc through the opening 143.

Accordingly, the semiconductor pattern 130c of the third transistor T3 may be electrically connected to the initialization voltage line 173 to receive the initialization voltage.

The connecting member 157 is electrically connected to the conductive area at the end of the semiconductor pattern 130a located at each pixel PXa, PXb, PXc through the opening 142, and can be electrically connected to the driving voltage line 172 underneath through the opening 146.

Accordingly, the semiconductor pattern 130a of the first transistor T1 may be electrically connected to the driving voltage line 172 to receive a driving voltage.

The connecting member 158 may be electrically connected to the capacitor pattern 134 and the second conductive pattern 175 positioned in each of the pixels PXa, PXb, PXc through the opening 145.

Accordingly, since the second conductive pattern 175 overlapping the channel region 130ac of the first transistor T1 receives the same voltage as that of the capacitor pattern 134 connected to the anode to be described later, reliability of the first transistor T1 is increased.

The connecting member 159 may be electrically connected to the common voltage line 170 through the opening 147.

The connecting member 159 is electrically connected to the horizontal voltage line 152 and may extend substantially along the horizontal voltage line 152 in a second direction DR2. Accordingly, the horizontal voltage line 152 may transmit the driving low voltage ELVSS in the first direction DR1.

At least one of the first conductive layer and the second conductive layer is copper (Cu), aluminum (A1), magnesium (Mg), silver (Ag), gold (Au), platinum (Pt), palladium (Pd), nickel (it may contain at least one of metals such as Ni), neodymium (Nd), iridium (Ir), molybdenum (Mo), tungsten (W), titanium (Ti), chromium (Cr), tantalum (Ta), alloys thereof, and the like.

At least one of the first conductive layer, the second conductive layer, and at least one of the conductive layer may include a single layer or multiple layers (e.g. Ti/Cu).

A third insulating layer 160 may be positioned on the second conductive layer.

The third insulating layer 160 includes an opening 165a positioned on the connecting member 158 of the first pixel PXa, and an opening 165b positioned on the connecting member 158 of the second pixel PXb, and an opening 167 positioned above the connecting member 159 may be included.

The third insulating layer 160 and the second insulating layer 140 may include an opening 165c positioned on the capacitor pattern 134 of the third pixel PXc.

A third conductive layer including a common electrode 270 may be positioned on the third insulating layer 160.

The common electrode 270 may be formed on a large portion of the entire surface of the substrate 110, and may form a cathode of the light emitting diode ED.

Referring to FIG. 2 and FIG. 3, the common electrode 270 may have openings 275a, 275b, 275c with positions and shapes corresponding to the first gate electrode 154 of each pixel PXa, PXb, PXc in a plan view.

Through this, direct overlapping between the common electrode 270 and the first gate electrode 154 may be avoided, and coupling between the common electrode 270 and the first gate electrode 154 may be reduced.

The common electrode 270 may be electrically connected to the connecting member 159 through the opening 167 to receive the driving low voltage ELVSS.

The common electrode 270 may further have openings 271a, 271b, 271c respectively corresponding to the openings 165a, 165b, 165c of the pixels PXa, PXb, PXc in a plan view.

The third conductive layer may further include bridges 272a, 272b, 272c positioned in each of the openings 271a, 271b, 271c and spaced apart from the common electrode 270.

The bridge 272a can be electrically connected to the connecting member 158 of the first pixel PXa through the opening 165a of the third insulating layer 160 and can be electrically connected to the capacitor pattern 134 of the first pixel PXa and one end of the conductive region of the first transistor T1.

The bridge 272b may be electrically connected to the connecting member 158 of the second pixel PXb through the opening 165b of the third insulating layer 160, and may be electrically connected to the capacitor pattern 134 of the second pixel PXb and one end of the conductive region of the first transistor T1.

The bridge 272c may be electrically connected to the capacitor pattern 134 of the third pixel PXc and the conductive region of one end of the first transistor T1 through the opening 165c of the third insulating layer 160.

A fourth insulating layer 370 may be positioned on the third conductive layer.

Referring to FIG. 3 to FIG. 6, the fourth insulating layer 370 is positioned on the common electrode 270 and can have a plurality of openings 375a, 375b, 375c defining the light emitting regions PXLa, PXLb, PXLc of each pixel PXa, PXb, PXc.

The fourth insulating layer 370 may have a plurality of openings 372a, 372b, 372c positioned over the plurality of openings 165a, 165b, 165c of the third insulating layer 160, respectively.

According to the embodiment, the opening 372a of the fourth insulating layer 370 may be positioned on the bridge 272a, the opening 372b may be positioned on the bridge 272b, and the opening 372c may be positioned on the bridge 272c.

Any of the first, second, third, or fourth insulating layers 120, 140, 160, or 370 may be an inorganic insulating material or an organic insulating material. At least one of the first insulating layer 120, the second insulating layer 140, the third insulating layer 160, and the fourth insulating layer 370 may be silicon oxide (SiOₓ), silicon nitride oxide (SiON), or silicon nitride (SiNₓ).

In particular, the third insulating layer 160 and the fourth insulating layer 370 may include an organic insulating material such as polyimide, an acryl-based polymer, or a siloxane-based polymer, and may have substantially flat upper surfaces.

A separation member 390 may be positioned on a portion of the fourth insulating layer 370.

The separation member 390 is a member for separating the plurality of pixel electrodes 191a, 191b, 191c for each region of each pixel PXa, PXb, PXc to separate them from each other, as shown in FIG. 2 and FIG. 3, similarly, each of the pixels PXa, PXb, PXc may have a planar shape surrounding the pixel circuit region and the emission regions PXLa, PXLb, PXLc.

In FIG. 3, the separation member 390 surrounding the pixel circuit area and the light emitting region PXLa of the first pixel PXa is denoted as the first separation member 390a, the separation member 390 surrounding the pixel circuit area and the light emitting region PXLb of the second pixel PXb is denoted as the second separation member 390b, and the separation member 390 surrounding the pixel circuit area and the light emitting region PXLc of the third pixel PXc is denoted as the third separation member 390c.

Each of the first separation member 390a, the second separation member 390b, and the third separation member 390c may form a closed curve surrounding each pixel electrode 191a, 191b, 191c.

The first separation member 390a, the second separation member 390b, and the third separation member 390c may be connected to form one integral body.

In FIG. 4 to FIG. 6, the separation member 390 is positioned on the upper surface of the fourth insulating layer 370 in a cross-sectional view and protrudes above a predetermined height in the third direction DR3.

In a cross-sectional view, the horizontal width of the lower end of the separation member 390 adjacent to the fourth insulating layer 370 may have a reverse taper shape smaller than the transverse width of the upper end of the separation member 390.

The separation member 390 may include an insulating material.

A fourth conductive layer including a plurality of pixel electrodes 191a, 191b, 191c, and a separated pattern 190 may be positioned on the fourth insulating layer 370 and the separation member 390.

The plurality of pixel electrodes 191a, 191b, 191c and the separation pattern 190 may be physically and electrically separated from each other by the separation member 390.

That is, the plurality of pixel electrodes 191a, 191b, 191c may be separated from each other by the separation member 390.

The plurality of pixel electrodes 191a, 191b, 191c may be formed in contact with the upper surface of the fourth insulating layer 370, and the separation pattern 190 may be formed in contact with the upper surface of the separation member 390.

To this end, the height of the separation member 390 in the third direction DR3 may be appropriately adjusted.

The fourth conductive layer may be formed on most of the entire surface of the substrate 110, and the plurality of pixel electrodes 191a, 191b, 191c are anodes of the light emitting diodes ED of the pixels PXa, PXb, PXc.

Each of the pixel electrodes 191a, 191b, 191c may be electrically connected to corresponding bridges 272a, 272b, 272c through openings 372a, 372b, 372c.

Accordingly, each of the pixel electrodes 191a, 191b, 191c may be electrically connected to the first transistor T1 through the bridges 272a, 272b, 272c to receive a voltage.

According to the embodiment, some of the pixel electrodes 191a, 191b of multiple pixels PXa, PXb, PXc can be connected to the connecting member 158 of the second conductive layer through a bridge 272a, 272b as shown in FIG. 4 and FIG. 5, and can again be electrically connected to the first transistor T1 through the connecting member 158.

As shown in FIG. 6, the pixel electrode 191c of some of the pixels PXa, PXb, PXc are electrically connected to the first transistor T1 through the bridge 272c directly connected to the semiconductor layer.

The structure in which the pixel electrodes 191a, 191b, 191c are connected to the first transistor T1 through the second conductive layer or to the first transistor T1 without passing through the second conductive layer is the pixel PXa, PXb, PXc, may be selected according to the positional relationship between the light emitting regions PXLa, PXLb, PXLc and the pixel circuit.

A light emitting layer 380 may be positioned between the common electrode 270 and the pixel electrodes 191a, 191b, 191c.

The light emitting layer 380 includes portions positioned within the openings 375a, 375b, 375c of the fourth insulating layer 370.

As shown in the embodiment of FIG. 5 and FIG. 6, the light emitting layer 380 may be positioned only within the openings 375a, 375b, 375c. In another embodiment, the light emitting layer 380 may further include a portion positioned above the fourth insulating layer 370 and above the separation member 390.

In this case, the light emitting layers 380 of the adjacent pixels PXa, PXb, PXc may be separated from each other and spaced apart from each other by the separation member 390 similarly to the pixel electrodes 191a, 191b, 191c.

The light emitting layer 380 may include an organic light emitting material or an inorganic light emitting material.

The light emitting layer 380 positioned in the plurality of pixels PXa, PXb, PXc may emit light of different colors when a voltage is applied between the common electrode 270 and the pixel electrodes 191a, 191b, 191c. Light of the same color may be emitted.

Each of the pixel electrodes 191a, 191b, 191c, the light emitting layer 380, and the common electrode 270 may form a light emitting diode ED.

The light emitting diode ED may emit light from the entire surface.

That is, light emitted from the light emitting layer 380 may be emitted toward the front surface of the substrate 110—that is, upward through the pixel electrodes 191a, 191b, 191c.

Of the light emitted from the light emitting layer 380, light emitted to the common electrode 270 may be partially reflected by the common electrode 270 and emitted upward.

The third conductive layer including the common electrode 270 may include a semi-transmissive conductive material or a reflective conductive material, and may have a single- or multilayer structure.

The fourth conductive layer including the pixel electrodes 191a, 191b, 191c may include a conductive transparent material and may have a single- or multilayer structure.

For example, the third conductive layer may include a metal layer including at least one metal such as silver (Ag), and may further include a metal oxide layer such as indium tin oxide (ITO) or indium zinc oxide (IZO).

For example, the third conductive layer is a first layer containing a metal oxide such as ITO, a second layer positioned on the first layer and containing a metal such as silver (Ag), and a second layer positioned on the second layer containing a metal oxide such as ITO, and it may have a multilayer structure including a third layer containing a metal oxide.

Accordingly, the IR drop of the driving low voltage ELVSS—that is, the amount of voltage drop—can be reduced in the common electrode 270 compared to the structure positioned on the fourth conductive layer.

The fourth conductive layer may include a metal or metal alloy such as silver (Ag) or magnesium (Mg).

According to the embodiment, between the substrate 110 and the common electrode 270 of the light-emitting diode ED, there are a minimum number of layers to form a pixel circuit for driving the light-emitting diode ED, namely the first conductive layer, semiconductor layer, and the second conductive layer, and the insulating layers 120, 140 in between, therefore, the number of masks for patterning each layer such as photoetching can be reduced, the use of exposure equipment can be reduced, and the number of manufacturing processes of the display device can be reduced, reducing manufacturing time and manufacturing costs.

In this way, when the number of layers between the substrate 110 and the light emitting diode ED is minimized for reducing manufacturing costs, if one end of the capacitor Cst connected to the gate voltage node of the first transistor T1 is not located in the first conductive layer but in the second conductive layer or the semiconductor layer, there may not be enough layers or sufficient spacing between one end of the capacitor Cst and the cathode or anode of the light emitting diode ED. As a result, the capacitance or coupling of the parasitic capacitor between one end of the capacitor Cst and the cathode or anode of the light emitting diode ED may increase, and the influence of horizontal crosstalk may increase, which may cause display defects.

However, according to the embodiment, one end of the capacitor Cst connected to the gate voltage node of the first transistor T1 among the terminals of the pixel circuit capacitor Cst is located in the first conductive layer closest to the substrate 110 as the first conductive pattern 174.

Therefore, as shown in FIG. 4 to FIG. 6, the distance Dg in the third direction DR3 in cross-section between the light emitting diode ED and the first conductive pattern 174, which is one end of the capacitor Cst, can be maximized.

Accordingly, horizontal crosstalk can be reduced by minimizing coupling between one end of the capacitor Cst connected to the gate voltage node of the first transistor T1 and the common electrode 270 of the light emitting diode ED.

In addition, coupling between one end of the capacitor Cst of one pixel PXa, PXb, PXc and the pixel electrodes 191a, 191b, 191c of the light emitting diode ED of the adjacent pixels PXa, PXb, PXc is minimized, which can also reduce color crosstalk.

In particular, in this embodiment, since the pixel electrodes 191a, 191b, 191c are positioned in the fourth conductive layer farther from the first conductive pattern 174, which is one end of the capacitor Cst, than the structure in which the pixel electrodes 191a, 191b, 191c are positioned in the third conductive layer, coupling between one end of the capacitor Cst of the pixels PXa, PXb, PXc and the pixel electrodes 191a, 191b, 191c of the light emitting diode ED of the adjacent pixels PXa, PXb, PXc can be further minimized.

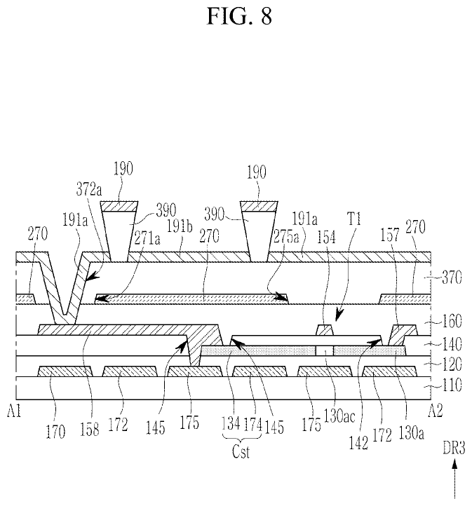

A display device according to an embodiment will be described with reference to FIG. 8 to FIG. 10 together with the previously described drawings.

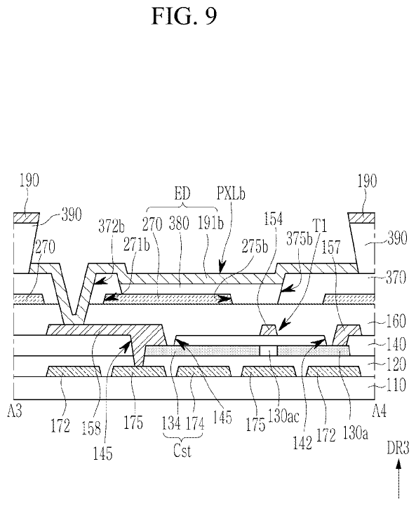

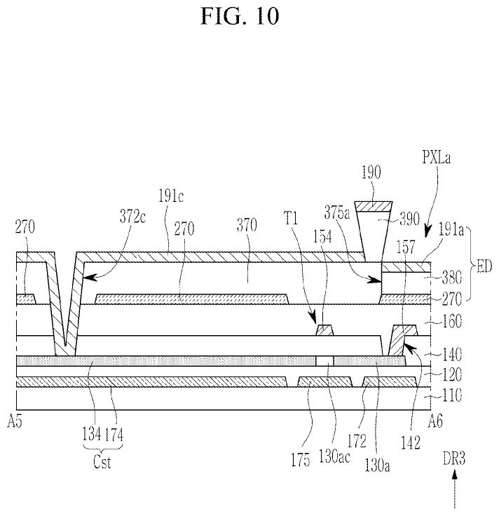

FIG. 8 is a cross-sectional view of the display device shown in FIG. 2 and FIG. 3 taken along line A1-A2, and FIG. 9 is a cross-sectional view taken along line A3-A4 of the display device shown in FIG. 2 and FIG. 3. FIG. 10 is a cross-sectional view of the display device shown in FIG. 2 and FIG. 3 cut along line A5-A6.

Referring to FIG. 8 to FIG. 10, the display device according to one embodiment is substantially the same as the display device according to the previously described embodiment, but the bridges 272a, 272b, 272c of the third conductive layer may be omitted.

That is, the pixel electrodes 191a, 191b, 191c may directly contact and electrically connect to the connecting member 158 or the capacitor pattern 134 without passing through the bridges 272a, 272b, 272c that are the third conductive layer.

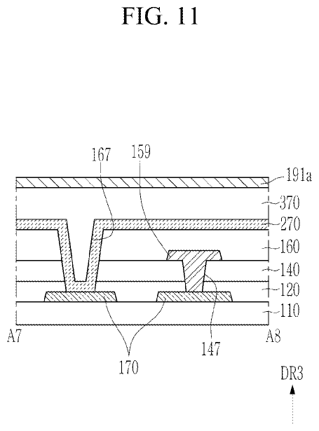

The display device according to an embodiment will be described with reference to FIG. 11 together with the previously described drawings.

FIG. 11 is a cross-sectional view of the display device shown in FIG. 2 and FIG. 3 cut along line A7-A8.

Referring to FIG. 2 and FIG. 11, the display device according to one embodiment is substantially the same as the display device according to the previously described embodiment, but the common electrode 270 is directly connected without passing through the connecting member 159 of the second conductive layer, it contacts the common voltage line 170.

In this case, unlike shown in FIG. 7, a region of the connecting member 159 overlapping the opening 167 may be removed.

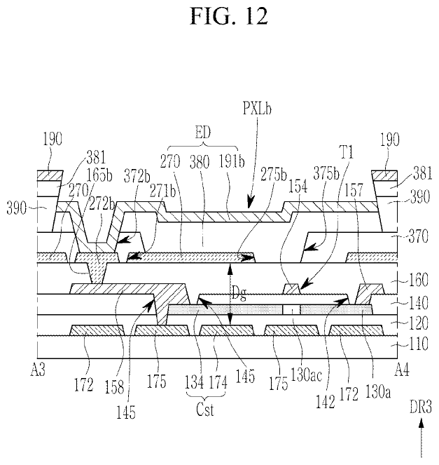

The display device according to an embodiment will be described with reference to FIG. 12 together with the previously described drawings.

FIG. 12 is a cross-sectional view of the display device shown in FIG. 2 and FIG. 3 taken along line A3-A4.

Referring to FIGS. 3 and 12, the display device according to one embodiment is mostly the same as the display device described earlier, but the light emitting layer 380 may further include parts located not only inside the openings 375a, 375b, 375c corresponding to the light-emitting areas PXLa, PXLb, PXLc, but also on top of the fourth insulating layer 370 and on the separation member 390.

In this case, the light emitting layers 380 of the neighboring pixels PXa, PXb, PXc may be separated from each other and spaced apart from each other by the separation member 390.

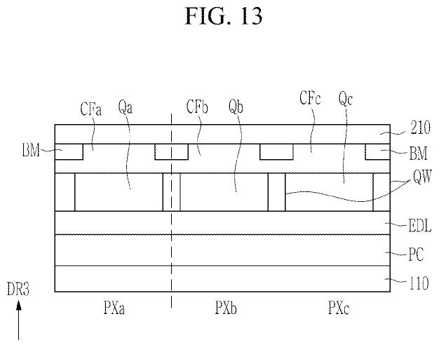

The display device according to an embodiment will be described with reference to FIG. 13 along with the previously described drawings.

FIG. 13 is a schematic cross-sectional view of the display device according to an embodiment.

Referring to FIG. 13, in the display device according to an embodiment, as described above, a pixel circuit layer PC including a pixel circuit including a plurality of transistors and capacitors Cst is positioned on a substrate 110, and a pixel circuit layer PC is disposed thereon, and a light emitting device layer EDL including light emitting diodes may be positioned thereon.

At least one insulating layer may be positioned on the light emitting device layer EDL, and a plurality of color conversion layers Qa, Qb and a transmission layer Qc may be positioned thereon.

The pixels PXa, PXb, PXc shown in FIG. 13 are exemplary, and arrangements are not limited to those shown in the drawing.

The transmission layer Qc may transmit incident light.

For example, the transmission layer Qc may transmit the first color light emitted from the light emitting layer 380 described above.

The first color light may be, for example, blue light, but is not limited thereto.

The region where the penetration layer Qc is located can correspond to the light emitting region that emits blue light, and the penetration layer Qc can pass through the incident first color light as it is without containing separate semiconductor nano-crystals.

The color conversion layers Qa, Qb may include different semiconductor nanocrystals.

For example, the first color light incident to the color conversion layer Qa may be converted into second color light by semiconductor nanocrystals included in the color conversion layer Qa and then emitted.

The first color light incident to the color conversion layer Qb may be converted into third color light by semiconductor nanocrystals included in the color conversion layer Qb and then emitted.

The semiconductor nanocrystals may include at least one of a phosphor and a quantum dot material that converts incident first color light into second color light or third color light.

A partition wall QW may be positioned between the adjacent color conversion layers Qa, Qb and the transmission layer Qc.

A plurality of color filters CFa, CFb, CFc and a light blocking member BM may be positioned on the plurality of color conversion layers Qa, Qb and the transmission layer Qc.

The color filter CFa can emit second color light, the color filter CFb can emit third color light, and the color filter CFc can emit first color light.

A substrate 210 may be positioned on the plurality of color filters CFa, CFb, CFc and the light blocking member BM.

According to another embodiment, instead of including the plurality of color conversion layers Qa, Qb and the transmission layer Qc, the light emitting layer 380 described above may include quantum dots.

Although embodiments of the present inventive concepts have been described, various modifications and similar arrangements of such embodiments will be apparent to a person of ordinary skill in the art. Accordingly, the inventive concepts are not limited to such embodiments, but rather to the scope and spirit of the appended claims.

What is claimed is:

1. A display device, comprising:
a substrate;
a first conductive layer disposed on the substrate and including a first conductive pattern;
a first insulating layer disposed on the first conductive layer;
a semiconductor layer disposed on the first insulating layer and including a first channel region and a capacitor pattern;
a second insulating layer disposed on the semiconductor layer;
a second conductive layer disposed on the second insulating layer and including a first gate electrode overlapping the first channel region;
a third insulating layer disposed on the second conductive layer;
a third conductive layer disposed on the third insulating layer and including a common electrode;
a fourth insulating layer disposed on the third conductive layer;
a fourth conductive layer disposed on the fourth insulating layer and including a plurality of pixel electrodes; and
a light emitting layer disposed between the pixel electrode and the common electrode,
wherein the first gate electrode is electrically connected to the first conductive pattern through a first opening formed in the first insulating layer and the second insulating layer,
the pixel electrode is electrically connected to the capacitor pattern, and
the capacitor pattern overlaps the first conductive pattern with the first insulating layer interposed therebetween to form a capacitor.

2. The display device of claim 1, wherein:
the fourth insulating layer has a plurality of second openings positioned over the common electrode, and
the light emitting layer includes a portion disposed in the second opening.

3. The display device of claim 2, further comprising:
a separation member disposed on a portion of the fourth insulating layer,
wherein the plurality of pixel electrodes are separated from each other with the separation member interposed therebetween.

4. The display device of claim 3, wherein:
the separation member includes a portion forming a plurality of closed curved lines surrounding each of the plurality of pixel electrodes in a plan view.

5. The display device of claim 4, wherein:
the fourth conductive layer further includes a separation pattern electrically and physically separated from the plurality of pixel electrodes and disposed on the separation member.

6. The display device of claim 5, wherein:
the second conductive layer further includes a first connecting member electrically connected to the capacitor pattern through a second opening formed in the second insulating layer, and
a first pixel electrode among the plurality of pixel electrodes is electrically connected to the first connecting member through a third opening formed in the fourth insulating layer and the third insulating layer.

7. The display device of claim 6, wherein:
a second pixel electrode among the plurality of pixel electrodes is electrically connected to the capacitor pattern through a fourth opening formed in the fourth insulating layer, the third insulating layer, and the second insulating layer.

8. The display device of claim 5, wherein:
the second conductive layer further includes a first connecting member electrically connected to the capacitor pattern through a second opening formed in the second insulating layer,
the third conductive layer further includes a first bridge electrically connected to the first connecting member through a third opening formed in the third insulating layer, and
a first pixel electrode among the plurality of pixel electrodes is electrically connected to the first bridge through a fourth opening formed in the fourth insulating layer.

9. The display device of claim 8, wherein:
the third conductive layer further includes a second bridge electrically connected to the capacitor pattern through a fifth opening formed in the third insulating layer and the second insulating layer, and
a second pixel electrode among the plurality of pixel electrodes is electrically connected to the second bridge through a sixth opening formed in the fourth insulating layer.

10. The display device of claim 5, wherein:
the first conductive layer further includes a common voltage line,
the second conductive layer further includes a connecting member electrically connected to the common voltage line,
the common electrode is electrically connected to the connecting member.

11. The display device of claim 5, wherein:
the common electrode has an opening having a position and a shape corresponding to that of the first gate electrode.

12. The display device of claim 1, wherein:
the first conductive layer further comprises:
a common voltage line;
a driving voltage line;
an initialization voltage line; and
a plurality of data lines,
the semiconductor layer further comprises:
a plurality of first semiconductor patterns electrically connected to the plurality of data lines; and
a second semiconductor pattern including the first channel region,
wherein the second semiconductor pattern is electrically connected to the driving voltage line, and
the common electrode is electrically connected to the common voltage line.

13. The display device of claim 12, wherein:
the first conductive layer further includes a second conductive pattern spaced apart from the first conductive pattern,
the second conductive pattern overlaps the first channel region, and
the second conductive pattern is electrically connected to the capacitor pattern.

14. A display device, comprising:
a substrate;
a first conductive layer disposed on the substrate and including a first conductive pattern;
a semiconductor layer disposed on the first conductive layer and including a first channel region and a capacitor pattern;
a second conductive layer disposed on the semiconductor layer and including a first gate electrode overlapping the first channel region;
a third conductive layer disposed on the second conductive layer and including a first electrode;
a fourth conductive layer disposed on the third conductive layer and including a plurality of second electrodes; and
a light emitting layer disposed between the first electrode and the second electrode,
wherein the first gate electrode being electrically connected to the first conductive pattern,
the second electrode being electrically connected to the capacitor pattern,
the capacitor pattern overlapping the first conductive pattern to form a capacitor, and
the first channel region and the capacitor pattern being integrally formed.

15. The display device of claim 14, further comprising:
a separation member disposed on the third conductive layer,
wherein the plurality of second electrodes are spaced apart from each other with the separation member interposed therebetween.

16. The display device of claim 15, wherein:
the separation member includes a portion forming a plurality of closed curves surrounding each of the plurality of second electrodes in a plan view.

17. The display device of claim 16, wherein:
the fourth conductive layer further includes a separation pattern electrically and physically separated from the plurality of second electrodes and disposed on the separation member.

18. The display device of claim 17, wherein:
the second electrode is electrically connected to the capacitor pattern through at least one first connecting member included in at least one of the second conductive layer and the third conductive layer.

19. The display device of claim 18, wherein:
the first conductive layer further includes a common voltage line, and
the first electrode is electrically connected to the common voltage line through at least one second connecting member included in the second conductive layer.

20. The display device of claim 17, wherein:
the first electrode has an opening corresponding to the first gate electrode.
